(19) United States
(12) Patent Application Publication
(10) Pub. No.: US 2005/0268202 A1
(43) Pub. Date: Dec. 1, 2005

(54) Quasi-block diagonal low-density parity-check code for MIMO systems

(76) Inventors: Andreas F. Molisch, Arlington, MA (US); Daqing Gu, Burlington, MA (US); Jinyun Zhang, Cambridge, MA (US); Jianxuan Du, Belmont, MA (US); Ye Li, Marietta, GA (US)

Correspondence Address: Patent Department;Mitsubishi Electric Research Laboratories, Inc., 201 Broadway, Cambridge, MA, 02139, US

(21) Appl. No.: 10/857,042

(22) Filed: May 28, 2004

(51) Int. Cl. G11C 29/00

(52) U.S. Cl. 714/752

(57) ABSTRACT

A method codes multiple data streams in multiple-input, multiple-output communications systems. In a transmitter, an input bitstream is encoded as codewords b in multiple layers. Each layer is modulated. A quasi-block diagonal, low-density parity-check code is applied to each layer, the quasi-block diagonal, parity-check code being a matrix H, the matrix H including one row of blocks for each subcode, and one row of blocks for each layer such that Hb=0 for any valid codeword. The layers are then forwarded to transmit antennas as a transmitted signal x.

### FIELD OF THE INVENTION

This invention relates generally to multiple-input, multiple-output communications systems, and more particularly to systems that transmit multiple data streams via multiple transmit antennas.

### BACKGROUND OF THE INVENTION

The capacity of multiple-input, multiple-output (MIMO) wireless communication systems, i.e., systems with multiple antennas at both the transmitter and receiver, can increase linearly with the number of antennas, G. J. Foschini and M. J. Gans, “On the limits of wireless communications in a fading environment when using multiple antennas,” Wireless Personal Commun., Vol. 6. pp. 315-335, March 1998, and Telatar, “Capacity of multi-antenna Gaussian channels,” European Transactions on Telecommunications, Vol. 10, pp. 585-595, November-December 1999.

An important factor that determines a performance of a MIMO system is an error correction code used to encode data. For single-input, single-output (SISO) systems, near-capacity achieving error correcting codes are known, e.g., low-density, parity-check (LDPC) codes, R. G. Gallager, Low-Density Parity-Check Codes, Cambridge, Mass., MIT Press, 1963, D. J. C. MacKay, “Good error-correcting codes based on very sparse matrices,” IEEE Trans. Inform. Theory, Vol. 45, pp. 399-431, March 1999, and Y. Kou, S. Lin, and M. P. C. Fossorier, “Low-density parity-check codes based on finite geometries: a rediscovery and new results,” IEEE Trans. Inform. Theory, Vol. 47, pp. 2711-2736, November 2001. Those types of capacity-approaching error correcting codes are well suited for implementation in integrated circuits due to their inherent parallelizability.

Irregular codes that are very close to the well known Shannon limit are also known, S. Y. Chung, G. D. Formey Jr., T. J. Richardson, R. Urbanke, “On the design of low-density parity-check codes within 0.0045 dB of the Shannon limit,” IEEE Commun. Lett., Vol. 5, pp. 58-60, February 2001, T. J. Richardson, M. A. Shokrollahi, and R. L. Urbanke, “Design of capacity-approaching irregular low-density parity-check codes,” IEEE Trans. Inform. Theory, Vol. 47, pp. 619-637, February 2001, and M. G. Luby, M. Mitzenmacher, M. A. Shokrollahi, and D. A. Spielman, “Improved low-density parity-check codes using irregular graphs,” IEEE Trans. Inform. Theory, Vol. 47, pp. 585-598, February 2001.

The problem with direct iterative decoding in MIMO systems is the extraction of a posteriori probabilities of bits from a received signal vector, which is the superposition of all transmitted signals. The derivation of the a posteriori probability requires an exhaustive search of all possible signal combinations.

For a 4×4 MIMO system with 64 quadrature amplitude modulation (QAM), the total number of possible combinations is 64⁴, which is impossible to search in real time. List decoding can dramatically reduce the complexity. Still, a large list is required to achieve acceptable performance for systems of higher order modulation.

Layered space-time structures can be used, such as systems that use V-BLAST, G. J. Foschini, “Layered space-time architecture for wireless communication in a fading environment when using multi-element antennas,” Bell Labs Technical Journal, pp. 41-59, August 1996. There, each antenna is used to transmit independently coded data streams (layers). The streams can be decoded efficiently by linear-processing to null undecoded layers and decision-feedback to cancel the interference from previously decoded layers. The problem is the presence of error-propagation.

The first layers that are decoded usually have low signal-to-noise ratio (SNR), due to loss of signal power by nulling according to zero-forcing or a minimum-mean-square-error (MMSE) criterion. The interference-cancellation by subtracting the reconstructed signal of incorrectly decoded layers only increase the interference, making the successful decoding of subsequent layers less likely.

### SUMMARY OF THE INVENTION

The invention provides a system and method for encoding and decoding wireless signals. The system uses a layered structure for space-time transmission with correlation between successive layers.

Instead of demultiplexing the input data into separate streams and encoding each stream independently, we extract information from layers that are encoded later to improve the detection performance of a current layer, which reduces error propagation in decision-feedback interference cancellation detectors.

A method codes multiple data streams in multiple-input, multiple-output communications systems. In a transmitter, an input bitstream is encoded as codewords b in multiple layers. Each layer is modulated.

A quasi-block diagonal, low-density parity-check code is applied to each layer, the quasi-block diagonal, parity-check code being a matrix H, and the matrix H including one row of blocks for each subcode, and one row of blocks for each layer such that Hb=0 for any valid codeword.

The layers are then forwarded to transmit antennas as a transmitted signal x.

### BRIEF DESCRIPTION OF THE DRAWINGS

FIG. 1 is a block diagram of a multi-input, multi-output wireless communications system according to the invention;

FIG. 2 is a block diagram of a quasi-block diagonal LDPC space-time codes structure according the invention;

FIG. 3 is a block diagram of a decoder according to the invention; and

FIG. 4 is a block diagram of a Tanner graph used by the invention.

### DETAILED DESCRIPTION OF THE PREFERRED EMBODIMENT

System Structure

Transmitter

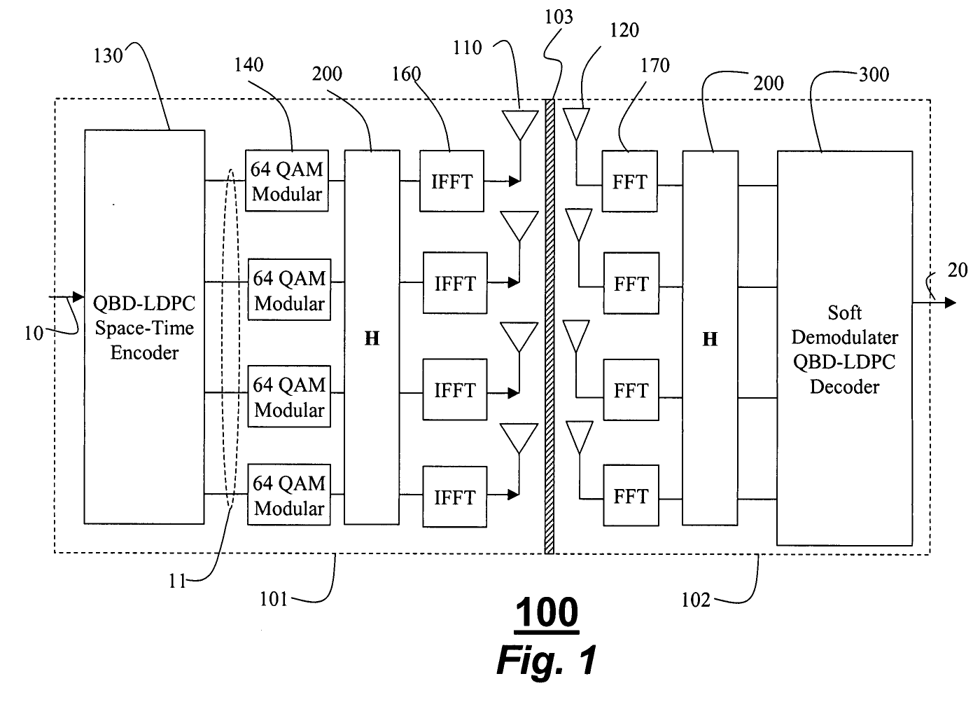

FIG. 1 shows a multi-input, multi-output (MIMO) system 100 that uses a parity check matrix structure 200 of a binary, quasi-block diagonal, low-density, parity-check code (QBD-LDPC). The system 100 includes a transmitter 101 and a receiver 102. The transmitter 101 includes four (Nₜ) transmit antennas 110, and the receiver has four (Nᵣ) receive antennas 120.

The transmitter includes an encoder 130. The encoder produces codewords b in multiple layers 11 from an input bit stream 10. Each layer is passed to a corresponding modulator 140. There is one modulator 140 for each encoded layer. In this example, the modulation is according to 64 QAM.

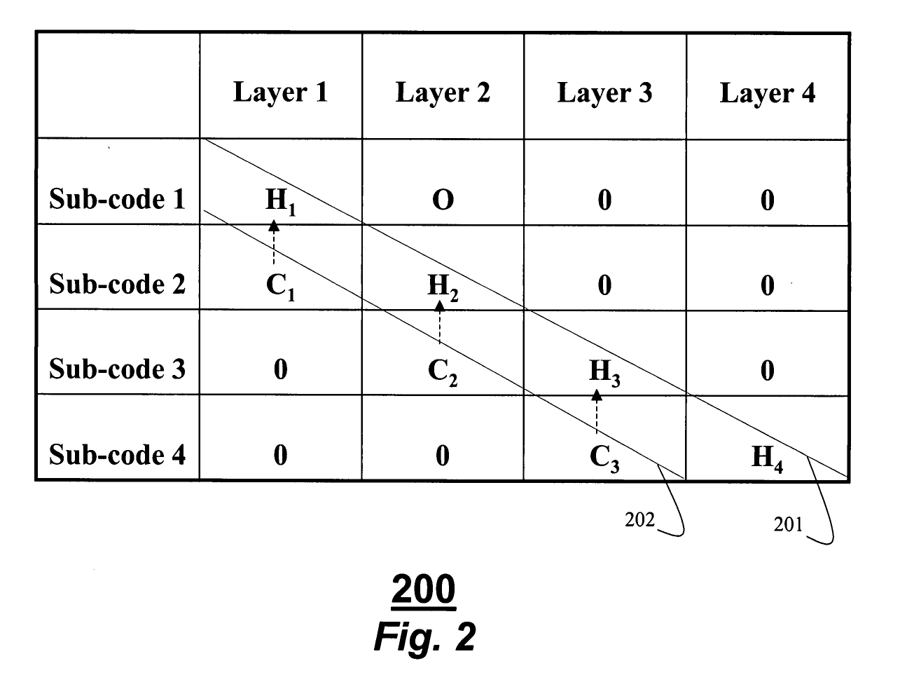

A quasi-block diagonal, low-density parity-check code, in the form of a matrix H 200 is applied to each layer. The structure of the matrix H 200 is described in detail below with reference to FIG. 2.

After the matrix H 200 is applied, each layer can be passed through an inverse fast Fourier transform (IFFT) 160, one for each layer. Then, the layers are forwarded to the transmit antennas 110 to form a transmitted signal x. Note that the output signals corresponding to each layer are permutated so that different parts of a layer are sent via different transmit antennas. The permutation is to guarantee that all layers have similar channel condition on the average. It should be understood that the proposed structure is not limited to OFDM systems.

Channel

The signal x is transmitted through a channel 103 to the Nᵣ receiver antennas 120. In the channel, the transmitted signal is subject to white Gaussian noise.

Receiver

In the receiver 102, a FFT 170 is applied to each layer of a received signal y, followed by the application of the matrix H 200. Then the signals are decoded 300 to produce an output bitstream 20 corresponding to the input bitstream.

Quasi-Block Diagonal Low-Density Parity-Check Code (QBD-LDPC)

FIG. 2 shows the quasi-block diagonal LDPC space-time codes structure 200 according the invention. In FIG. 2, the four sub-codes 1-4 are indicated in the rows, and the four corresponding layers 1-4 in the columns.

The entire matrix 200 is denoted as H, and any valid binary codeword b satisfies the equation
Hb=0.

The codewords b of each layer have identical lengths. However, the code rates for the codewords are different for different layers. This implies that the number of the information bits are different. The code rates increase according to an order of detection of the layers because the first layer detected has a lowest channel quality, after nulling, than later detected layers.

The blocks along the main diagonal 201 of the matrix H 200 indicate the corresponding check matrices Hᵢ for each layer. The blocks along a diagonal 202 directly below the main diagonal 201 indicate connection matrices Cᵢ. The connection matrices Cᵢ link two consecutive layers i and i+1 as an exchange for information between the subcodes of the layers. For all other blocks, the connecting matrices Cᵢ are codewords.

In a practical application, the matrix H 200 can be implemented as a Tanner graph, with nodes and message passing as described below. Tanner graphs are well known, although Tanner graphs have not been used for a binary, quasi-block diagonal, low-density, parity-check code according to the invention.

The layers are decoded in order from a first layer 1 to a last layer 4 and, at detection stage i, a next layer i+1 also contributes to the decoding of a previous layer i according to the connecting matrices Cᵢ.

It is known that bits or variable nodes with higher degrees tend to converge faster, Chung et al., “Analysis of sum-product decoding of low-density parity-check codes using a Gaussian approximation,” IEEE Trans. Inform. Theory, Vol. 47, pp. 657-670, February 2001. This has motivated the design of irregular LDPC because the faster converging bits make it easier to decode the remaining bits.

This motivates our use of connection matrices Cᵢ according to the invention. Those matrices can be regarded as adding degrees to bits in the layer i so that those bits are better protected. In other words, when decoding layer i, the matrices Hᵢ, Hᵢ₊₁, and Cᵢ form a smaller subcode where only the bits related to the matrix Hᵢ with higher degrees are to be decoded at a current stage. The decoding of layer i+1 is be carried out later, with better channel quality after canceling the interference from layer i, and with more protection, because layer i+2 contributes to the decoding.

Encoding

In the transrmitter 101, an input bitstream 10 is encoded 130. A length of each codeword for each layer is n. The number of parity check bits for layer i is rᵢ. The (n−rᵢ)×1 vector of input information bits is denoted as uᵢ. The encoding of first layer is straightforward.

By performing Gaussian elimination, we have
W₁H₁=(P₁I₁),
where the matrix W₁ is a r₁×r₁ full rank matrix performing Gaussian elimination on the matrix H₁, and the matrix P₁ is a r₁×(n−r₁) matrix, and the matrix I₁ is an r₁×r₁ identity matrix. This structure corresponds to the fact that the code is systematic. Then, the codeword for layer 1 is formed by
b=((P₁u₁)^{T}u₁^{T})^{T}.

For layer i (i>1), by performing Gaussian elimination, we have
WᵢHᵢ=(PᵢIᵢ),
and the codeword for layer i is formed by
bᵢ=((Pᵢuᵢ+WᵢCᵢ₋₁bᵢ₋₁)^{T}uᵢ^{T}).
where the matrix Wᵢ is a rᵢ×rᵢ matrix.

During the encoding with a non-codeword connection matrix Cᵢ₋₁, part of the information of layer i−1 is injected into the next codeword of layer i.

Decoding

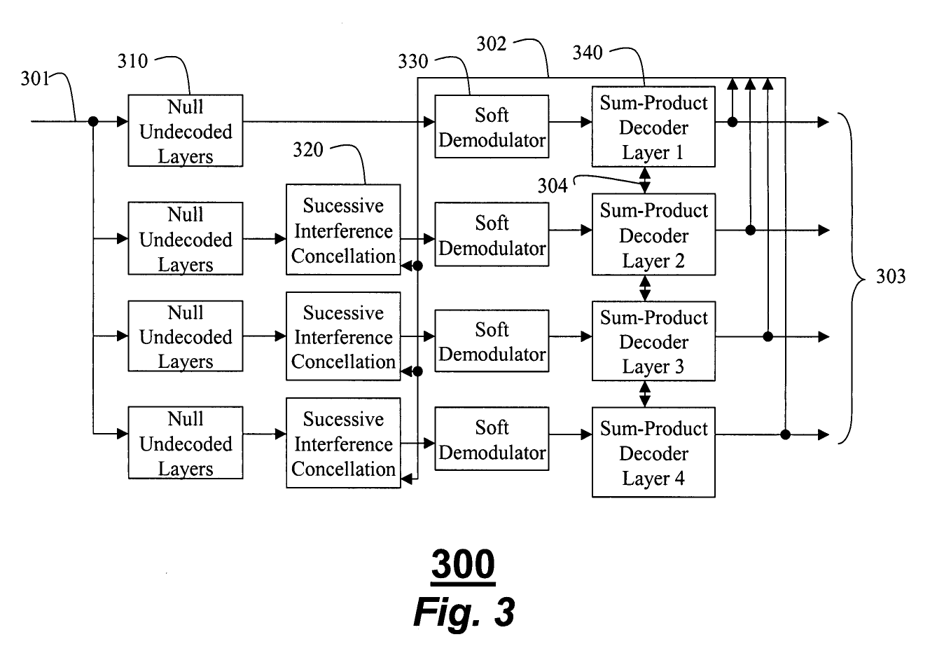

FIG. 3 shows the details of the decoder 300. In the receiver 102, the signal y 301 received through the channel 103 is a superposition of all transmitted signals distorted by the channel
y=Gx+n,
where y is a Nᵣ×1 received signal vector, x is an Nₜ×1 transmitted signal vector, the matrix G is an Nᵣ×Nₜ equivalent channel response matrix taking the permutation into account, and n is the Nᵣ×1 codeword-mean white Gaussian channel noise vector with a variance N₀/2 per dimension.

For simplicity, we do not explicitly specify the subcarrier or time index in the following generalization, where the number of transmit and receive antennas are Nₜ and Nᵣ, respectively. Without loss of generality, we assume that the i^{th} element of the vector x, denoted as xᵢ, is the signal from the i^{th} layer, corresponding to the i^{th} column of the matrix G, denoted as a vector gᵢ.

Assume we are now decoding layer i. Note that decoders for the layer i and i+1 are both active.

Linear Processing

The decoding uses linear processing according to
zⱼ=wⱼ^{H}y, j=i,i+1,
where a Nᵣ×1 unit-norm weight vector, wⱼ, nulls signals from undecoded layers and is determined according to nulling 310, i.e., nulling according to zero-forcing or MMSE criterion.

Interference Cancellation

Interference cancellation 320 is performed according to

$${\tilde{z}}_{j} = {z}_{j} - {\sum }_{i < j} {w}_{j}^{H} {g}_{i} {\hat{x}}_{i} , j = i , i + 1 ,$$

where \hat{x}ᵢ's are the reconstructed signals 303 of decoded layers that are used for decision feedback 302.

After linear processing and interference cancellation, the layers are decoded 340 as a one-dimensional code at each stage.

A log-likelihood ratio (LLR) is defined as

$$L ( b ) {=}^{Δ} ln ( \frac{p ( b = 1 )}{p ( b = 0 )} ) ,$$

where p indicates a probability of a codeword b.

Then soft information, i.e., a tentative codeword, from a demodulator 330 is

$${L}_{zb} ( {b}_{k} ) = ln \frac{{\sum }_{b : {b}_{k} = 1} p ( z \vert b ) {ⅇ}^{{\sum }_{i ∈ {V}_{k}} {L}_{bz} ( {b}_{l} )}}{{\sum }_{b : {b}_{k} = 0} p ( z \vert b ) {ⅇ}^{{\sum }_{i ∈ {V}_{k}} {L}_{bz} ( {b}_{l} )}} , j = i , i + 1 ,$$

where b is the codeword mapped to the received signal
xⱼ,Vₖ={l|l≠k and xₗ=1}, and

$$P ( z \vert b ) = \frac{1}{π {N}_{0}} {ⅇ}^{- \frac{1}{{N}_{0}} {\vert {\tilde{z}}_{j} - {w}_{j}^{H} {g}_{j} {x}_{j} \vert}^{2}} , j = i , i + 1 ,$$

for zero-forcing nulling.

The soft output from the demodulator 330 is then sent to a sum-product decoder 340.

Tanner Graph

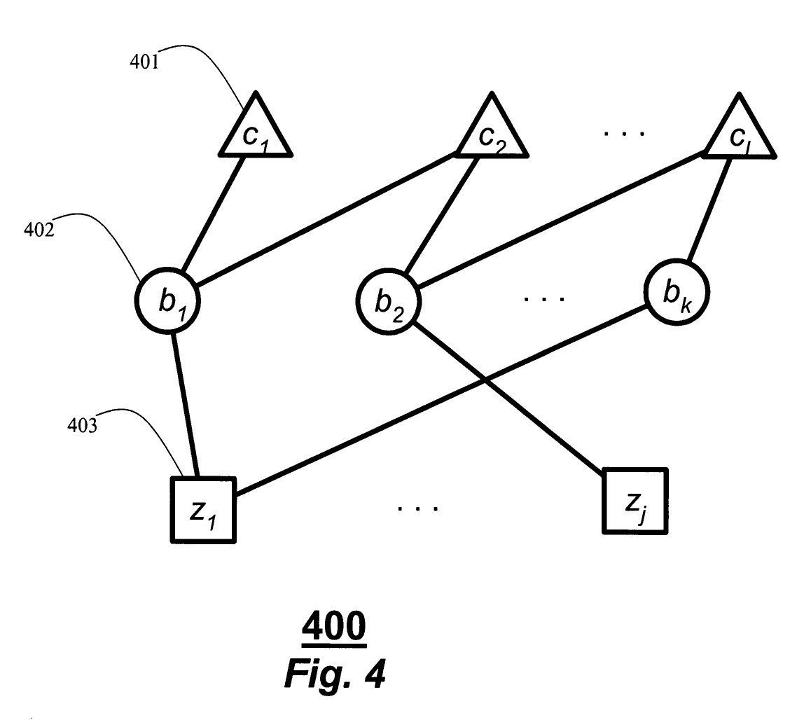

As shown in FIG. 4, the quasi-block diagonal, low-density parity-check code, i.e., the matrix H 200 can be represented as a Tanner graph 400 including codeword or variable nodes bₖ 402, check nodes cₖ 401, and observation nodes 403. An update message 304 at each codeword node is

$${L}_{bc} ( {b}_{k} , {c}_{l} ) = {L}_{zb} ( {b}_{k} ) + {\sum }_{{{c}_{j} ∈ Ω ( {b}_{k} )}_{{c}_{j} \neq {c}_{l}}} {L}_{cb} ( {b}_{k} , {c}_{j} ) ,$$

where Ω(bₖ) denotes a set of nodes that are neighboring nodes of each codeword bₖ node. An update message at each check node is

$${L}_{cb} ( {b}_{k} , {c}_{l} ) = L ( {\sum }_{{b}_{j} ∈ Ω ( {c}_{l} ) \backslash {b}_{k}} {b}_{j} ) ,$$

which can, for example, be implemented efficiently by a forward-backward process between arbitrary nodes a and b as

$$L ( a + b ) = ln \frac{{ⅇ}^{L ( a )} + {ⅇ}^{L ( b )}}{1 + {ⅇ}^{L ( a ) + L ( b )}} ,$$

or by a process described by Hu et al., “Efficient implementations of the sum-product algorithm for decoding LDPC codes,” GLOBECOM 2001, Vol. 2, pp. 25-29, November 2001.

Note that the message passing 304 is performed between layer i and i+1, as well as within each layer.

Then the message passed to a soft demodulator as a priori information is

$${L}_{bz} ( {b}_{k} ) = {\sum }_{{c}_{l} ∈ Ω ( {b}_{k} )} {L}_{cb} ( {b}_{k} , {c}_{l} ) .$$

The LLR for tentative decision 303 is

$$LLR ( {b}_{k} ) = {L}_{zb} ( {b}_{k} ) + {\sum }_{{c}_{l} ∈ Ω ( {b}_{k} )} {L}_{cb} ( {b}_{k} , {c}_{l} ) = {L}_{zb} ( {b}_{k} ) + {L}_{bz} ( {b}_{k} ) .$$

Although the invention has been described by way of examples of preferred embodiments, it is to be understood that various other adaptations and modifications may be made within the spirit and scope of the invention. Therefore, it is the object of the appended claims to cover all such variations and modifications as come within the true spirit and scope of the invention.

1. A method for coding multiple data streams in a multiple-input, multiple-output communications systems, comprising:
encoding, in transmitter, an input bitstream as codewords b in a plurality of layers;
modulating each layer;
applying a quasi-block diagonal, low-density parity-check code to each layer, the quasi-block diagonal, parity-check code being a matrix H, the matrix H including one row of blocks for each subcode, and one row of blocks for each layer such that Hb=0 for any valid codeword; and
forwarding the plurality of layers to a plurality of transmit antennas as a transmitted signal x.

2. The method of claim 1, in which codewords b of each layer have identical lengths, and a code rate for the codewords are different for different layers, and in which the length of each codeword b for each layer is n, and a number of parity check bits for the layer i is rᵢ.

3. The method of claim 2, in which the code rates increase according to an order of detection of the layers in a receiver.

4. The method of claim 1, in which the blocks along the main diagonal of the matrix H indicate corresponding check matrices Hᵢ for each layer, in which blocks along a diagonal below the main diagonal indicate connection matrices Cᵢ, the connection matrices Cᵢ linking two consecutive layers i and i+1 as an exchange for information between the subcodes of the layers, and in which all other blocks indicate connecting matrices Cᵢ that are zero.

5. The method of claim 4, in which the layers are decoded in a receiver in order from a first layer to a last layer, and at detection stage i, a next layer i+1 contributes to a decoding of a previous layer i according to the connecting check matrices Cᵢ.

6. The method of claim 1, further comprising:
receiving the plurality of layers as a received signal y;
applying the quasi-block diagonal, low-density parity-check code to each layer; and
decoding each layer to produce an output bitstream corresponding to the input bitstream.

7. The method of claim 6, in which the received signal y is
y=Gx+n,
where the received signal y a Nᵣ×1 vector, where Nᵣ is a number of receive antennas, the matrix G is an Nᵣ×Nₜ equivalent channel response matrix, where Nₜ is a number of transmit antennas, and n is a Nᵣ×1 zero-mean white Gaussian channel noise vector with a variance N₀/2 per dimension, and in which an i^{th} element of the vector x, denoted as xᵢ, is the received signal corresponding to i^{th} layer, corresponding to the i^{th} column of the matrix G, denoted as a vector gᵢ, in which the decoding uses linear processing according to
zⱼ=wⱼ^{H}y, j=i,i+1,
where a Nᵣ×1 unit-norm weight vector wⱼ nulls signals from undecoded layers.

8. The method of claim 7, in which the nulling is determined by zero-forcing.

9. The method of claim 7, in which the nulling is determined by a minimum-mean-square-error (MMSE) criterion.

10. The method of claim 7, further comprising:
canceling interference in the received signal according to
$${\tilde{z}}_{j} = {z}_{j} - {\sum }_{i < j} {w}_{j}^{H} {g}_{i} {\hat{x}}_{i} , j = i , i + 1 ,$$
where \hat{x}ᵢ are decoded layers used for decision feedback.

11. The method of claim 7, further comprising:
defining a log-likelihood ratio as
$$L ( b ) {=}^{Δ} ln ( \frac{p ( b = 1 )}{p ( b = 0 )} ) ,$$
where p indicates a probability of a particular codeword b, and
demodulating the codewords b according to
$${L}_{zb} ( {b}_{k} ) = ln \frac{{\sum }_{b : {b}_{k} = 1} p ( z \vert b ) {ⅇ}^{{\sum }_{i ∈ {V}_{k}}^{{L}_{bz} ( {b}_{1} )}}}{{\sum }_{b : {b}_{k} = 0} p ( z \vert b ) {ⅇ}^{{\sum }_{i ∈ {V}_{k}}^{{L}_{bz} ( {b}_{1} )}}} , j = i , i + 1 ,$$
where b is the codeword mapped to the received signal
xⱼ,Vₖ={l|l≠k and xₗ=1}, and
$$p ( z \vert b ) = \frac{1}{π {N}_{0}} {ⅇ}^{- \frac{1}{{N}_{0}} {\vert {\tilde{z}}_{j} - {w}_{j}^{H} {g}_{j} {x}_{j} \vert}^{2}} , j = i , i + 1 ,$$
for the nulling.

12. The method of claim 11, further comprising:
representing the quasi-block diagonal, low-density parity-check codes as a Tanner graph including codeword nodes bₖ and check nodes cₖ, in which an update message at each codeword node bₖ is
$${L}_{bc} ( {b}_{k} , {c}_{l} ) = {L}_{zb} ( {b}_{k} ) + {{\sum }_{{c}_{j} ∈ Ω ( {b}_{k} )}}_{{c}_{j} \neq {c}_{l}} {L}_{cb} ( {b}_{k} , {c}_{j} ) ,$$
where Ω(bₖ) denotes a set of nodes that are neighboring nodes of each codeword bₖ node, and an update message at each check node is
$${L}_{cb} ( {b}_{k} , {c}_{l} ) = L ( {\sum }_{{b}_{j} ∈ Ω ( {c}_{l} ) \backslash {b}_{k}} {b}_{j} ) .$$

13. The method of claim 12, further comprising:
implementing the update messages as a sum-product decoder.

14. The method of claim 13, in which the sum-product decoder uses a forward-backward process
$$L ( a + b ) = ln \frac{{ⅇ}^{L ( a )} + {ⅇ}^{L ( b )}}{1 + {ⅇ}^{L ( a ) + L ( b )}} .$$
